(19) United States
(12) Patent Application Publication
(10) Pub. No.: US 2015/0076975 A1
(43) Pub. Date: Mar. 19, 2015

(54) CONTAINER DATA CENTER

(71) Applicant: Huawei Technologies Co., Ltd., Shenzhen (CN)

(72) Inventors: Yonghui Peng, Shenzhen (CN); Feng Ao, Shenzhen (CN); Dongli Wang, Shenzhen (CN)

(21) Appl. No.: 14/552,093

(22) Filed: Nov. 24, 2014

Related U.S. Application Data
(63) Continuation of application No. PCT/CN2012/085426, filed on Nov. 28, 2012.

(30) Foreign Application Priority Data
May 23, 2012 (CN) 201210162314.2

(51) Int. Cl. H05K 7/14; H05K 7/20; H05K 5/02

(52) U.S. Cl. CPC H05K 7/1488; H05K 5/0213; H05K 5/0234; H05K 7/20218
USPC 312/201; 312/237; 312/236

(57) ABSTRACT

A container data center includes one container body and at least one cabinet set that is arranged in the container body in one direction. Each cabinet set includes at least one cabinet, and a direction in which the at least one cabinet is arranged is perpendicular to the direction in which the cabinet set is arranged. Bottoms of all cabinets in each cabinet set are fastened on one shock absorbing platform, and a bottom of the shock absorbing platform is fastened to a bottom of the container body by using multiple shock absorbers. The container data center can reduce an impact of vibration and a shock on a data center pipe in a transportation process.

### CROSS-REFERENCE TO RELATED APPLICATIONS

This application is a continuation of International Application No. PCT/CN2012/085426, filed on Nov. 28, 2012, which claims priority to Chinese Patent Application No. 201210162314.2, filed on May 23, 2012, both of which are hereby incorporated by reference in their entireties.

### TECHNICAL FIELD

The present invention relates to the field of communications, and in particular, to a container data center.

### BACKGROUND

As a low-cost, high-integration, energy-saving, flexible, and rapid-deployment modular data center solution, a container data center has been put into wide commercial application.

FIG. 1 shows a structure used for a container data center in the prior art, where R1 to R8 are cabinets. FIG. 2 shows a cutaway drawing of FIG. 1 in a width direction. In the solutions shown in FIG. 1 and FIG. 2, shock absorption is performed for each cabinet independently, and a gap exists between two cabinets 26 that are in one horizontal row (as shown in FIG. 2). Therefore, a risk of collisions and shocks exists between the cabinets. In addition, because each cabinet is independently connected to a container floor by using a shock absorber of the cabinet, a special tool is required for dragging, loading, and unloading, so that maintenance is inconvenient.

### SUMMARY

In view of this, an objective of the present invention is to provide a container data center that can be rapidly deployed and maintained, so as to reduce an impact of vibration and a shock on a data center pipe in a transportation process.

To implement the foregoing objective, an embodiment of the present invention provides a container data center, including one container body and at least one cabinet set that is arranged in the container body in one direction. Each cabinet set includes at least one cabinet, and a direction in which the at least one cabinet is arranged is perpendicular to the direction in which the cabinet set is arranged. Bottoms of all cabinets in each cabinet set are fastened on one shock absorbing platform, and a bottom of the shock absorbing platform is fastened to a bottom of the container body by using multiple shock absorbers.

Preferably, in each cabinet set, adjacent cabinets are disposed in a gapless manner.

Preferably, the data center further includes a cooling apparatus that is disposed inside the container body and configured to dissipate heat for the cabinet set.

Preferably, the cooling apparatus are liquid cooling cabinets, and the liquid cooling cabinets are disposed at two ends of each cabinet set in a direction in which a cabinet is arranged. Each liquid cooling cabinet is connected, by using a branch pipe, to a main pipe extending in a direction of the cabinet set, and the main pipe is configured to transport cooling water.

Preferably, one end of the main pipe is fastened to the container body, and the other end is free and not fastened.

Preferably, multiple main pipes are disposed. A bottom of each main pipe is fastened to at least one wheel, and all wheels at the bottom of each main pipe slide in a chute that is fastened at the bottom of the container body.

Preferably, the branch pipe is a rubber pipe.

Preferably, a rubber layer is further wrapped around the main pipe.

Preferably, a top of at least one cabinet in each cabinet set is connected, in a movable manner, to a beam on a top of the container by using a screw, so as to implement position limiting.

Preferably, a shaft sleeve is disposed on the beam on the top of the container, a projection of the shaft sleeve is located on the top of the at least one cabinet, and the at least one cabinet is connected, by using a screw, to the shaft sleeve corresponding to the top of the at least one cabinet, so as to implement a movable connection to the beam on the top of the container.

In the container data center provided in the embodiment of the present invention, cabinets are divided into multiple rows, cabinets in each row correspondingly form one cabinet set, bottoms of all cabinets in a same cabinet set are fastened on a same shock absorbing platform, and each shock absorbing platform is fastened to a bottom of a container by using multiple shock absorbers at a bottom of the shock absorbing platform. In this way, shock absorption is performed for all cabinets in a same cabinet set by using one shock absorbing platform and shock absorbers under the shock absorbing platform. In addition, to implement an objective of shock absorption, bottoms of all cabinets in one cabinet set only need to be connected to one shared shock absorbing platform. In this way, mounting difficulty is reduced in comparison with the prior art in which each cabinet needs to be directly connected to an independent shock absorber. In addition, by using this connection relationship, in the present invention, each cabinet can be fastened to the shock absorbing platform in a standard connection manner by using a standard connection hole at a bottom of the cabinet, without a need of an additional fastening and mounting device.

### BRIEF DESCRIPTION OF THE DRAWINGS

The following describes the present invention in detail according to embodiments and with reference to accompanying drawings. In the accompanying drawings:

FIG. 1 and FIG. 2 are schematic diagrams of a container data center in the prior art;

FIG. 3 is a top view of a container data center according to an embodiment of the present invention;

FIG. 4 is a cutaway drawing of the container data center in FIG. 3 in an A-A direction;

FIG. 5 is a schematic diagram of a liquid cooling cabinet and pipes of the liquid cooling cabinet in a container data center according to an embodiment of the present invention;

FIG. 6 is a bottom view of a container data center according to an embodiment of the present invention; and

FIG. 7 is a cross-sectional view of key parts near a main pipe of a container data center according an embodiment of the present invention.

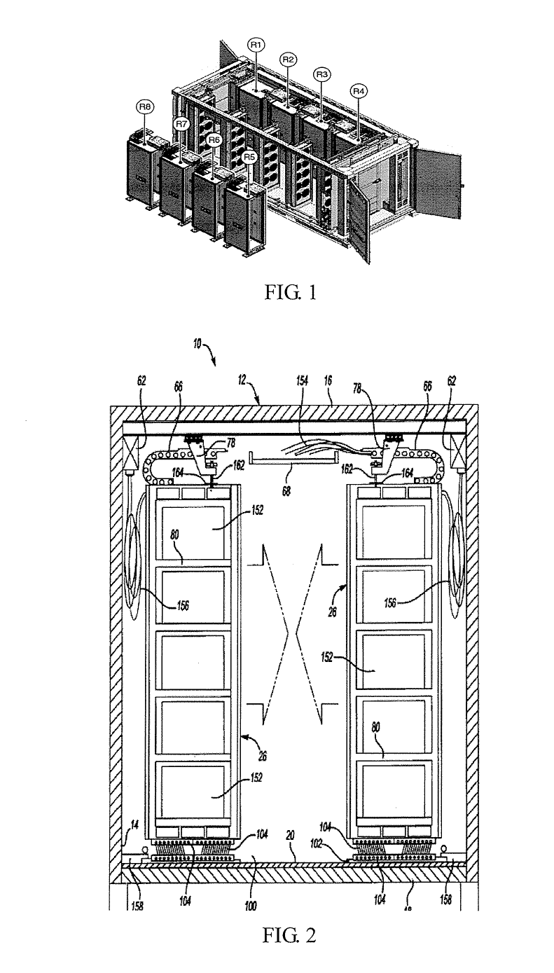

### DETAILED DESCRIPTION

An embodiment of the present invention provides a container data center. The container data center includes one container body. At least one cabinet set is arranged in the container body in one direction of the container body. Each cabinet set includes at least one cabinet, and a direction in which the at least one cabinet is arranged is perpendicular to the direction in which the cabinet set is arranged. Bottoms of all cabinets in each cabinet set are fastened on one shock absorbing platform. A bottom of each shock absorbing platform is fastened to a bottom of the container body by using multiple shock absorbers.

It can be seen that, in the container data center provided in the embodiment of the present invention, cabinets are divided into multiple rows, cabinets in each row form one cabinet set, bottoms of all cabinets in a same cabinet set are fastened on a same shock absorbing platform, and each shock absorbing platform is fastened to a bottom of a container by using multiple shock absorbers at a bottom of the shock absorbing platform. In this way, shock absorption is performed for all cabinets in a same cabinet set by using one shock absorbing platform and shock absorbers under the shock absorbing platform. In addition, to implement an objective of shock absorption, bottoms of all cabinets in one cabinet set only need to be connected to one shared shock absorbing platform. In this way, mounting difficulty is reduced in comparison with the prior art in which each cabinet needs to be directly connected to an independent shock absorber. In addition, by using this connection relationship, in the present invention, each cabinet can be fastened to the shock absorbing platform in a standard connection manner by using a standard connection hole at a bottom of the cabinet, without a need of an additional fastening and mounting device.

The following describes, in detail, a specific structure of the container data center provided in the present invention by using a specific example.

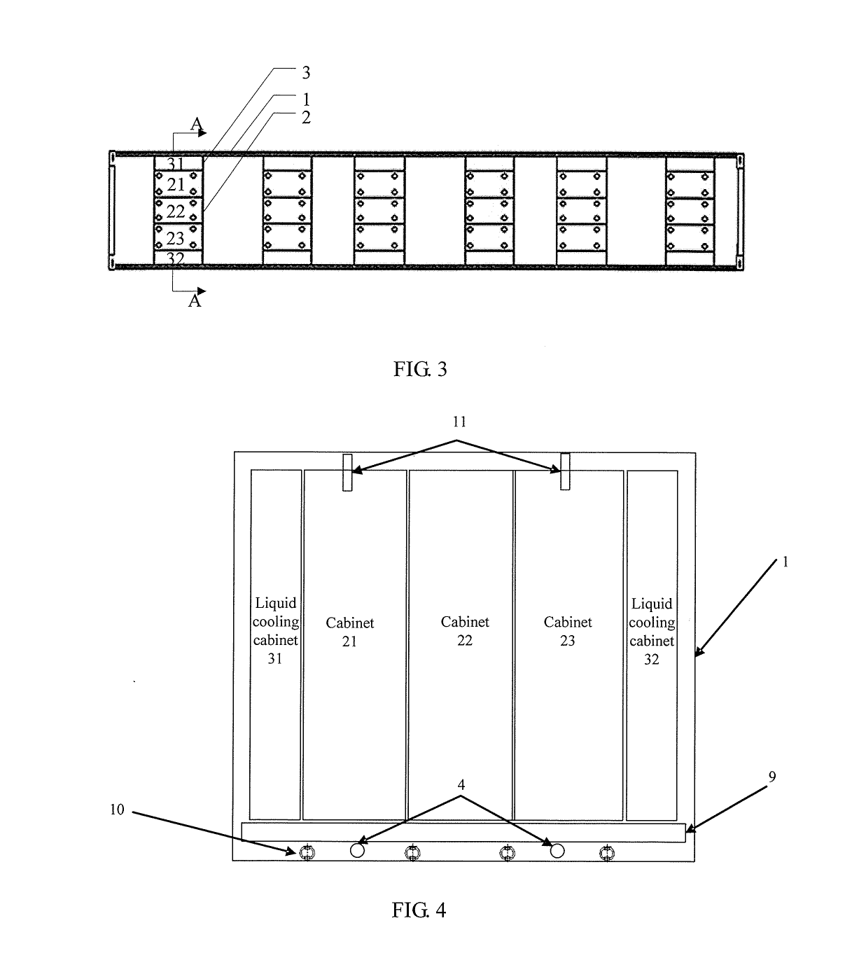

FIG. 3 shows a top view of the container data center in this embodiment, where it can be seen that, the container data center in this embodiment includes one container body 1, and 6 rows of cabinet sets 2 are arranged in a length direction of the container body 1. Each cabinet set 2 further includes 3 cabinets that are arranged in a width direction of the container body 1 and marked as a cabinet 21, a cabinet 22, and a cabinet 23.

FIG. 4 shows a cutaway drawing of the container data center in FIG. 3 in an A-A direction. As shown in FIG. 4, in this embodiment, preferably, in each cabinet set 2, adjacent cabinets are disposed in a gapless manner, so as to achieve an objective of a gapless rigid connection. In this way, vibration couplings, collisions, and impacts between cabinets can be avoided to a largest extent, and a utilization rate of space in the container body is also improved.

Bottoms of cabinets 21, 22, and 23 in a same cabinet set are fastened on one shared shock absorbing platform 9. A bottom of the shock absorbing platform 9 is fastened to a bottom of the container body by using multiple shock absorbers. For example, in FIG. 4, steel wire rope shock absorbers 10 are used as the shock absorbers at the bottom of the shock absorbing platform 9. After a maximum load capacity of a single shock absorber is known, the number of shock absorbers may be reasonably selected according to the number of cabinets in the cabinet set. If the number of cabinets in the cabinet set needs to be expanded, the number of shock absorbers under the shock absorbing platform may also be increased.

In addition, for the data center, a volume of data processed by the data center is large, causing a large heat volume in a working process of a cabinet. Therefore, a cooling apparatus needs to be disposed inside the container body to dissipate heat for the cabinet set. The cooling apparatus may work in an air cooling manner, for example, an air conditioner; and certainly, may also work in a water cooling manner, for example, a liquid cooling cabinet.

Referring to both FIG. 3 and FIG. 4, in this embodiment, in each cabinet set 2, one liquid cooling cabinet is disposed on each of two ends of a direction in which the cabinets 21, 22, and 23 are arranged, and marked as a liquid cooling cabinet 31 and a liquid cooling cabinet 32. The liquid cooling cabinet and the bottom of the cabinet set are fastened on the shock absorbing platform 9. Each liquid cooling cabinet is connected, by using a branch pipe, to a main pipe extending in a direction in which the cabinet set is arranged. For example, FIG. 5 shows a schematic diagram of two liquid cooling cabinets at two ends of one cabinet set, where liquid cooling cabinets 31 and 32 are both connected to a main pipe 4 by using a respective branch pipe 5.

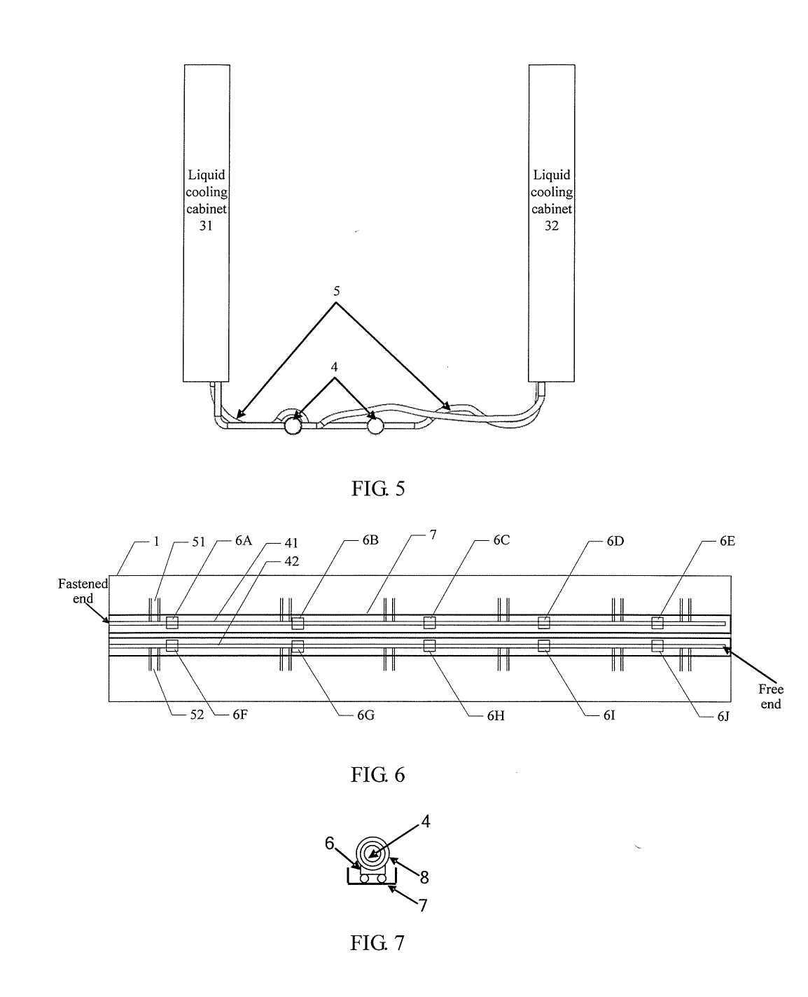

In addition, in this embodiment, one end of the main pipe is connected and fastened to the container body 2, and the other end is free and not fastened. For example, FIG. 6 shows a bottom view of this embodiment, where left ends of two main pipes 41 and 42 are connected to the container body 2 in a rigid manner, and right ends are freely and not fastened. The main pipe 41 is connected to a branch pipe 51 of a liquid cooling cabinet disposed near a side of the main pipe 41, and the main pipe 42 is connected to a branch pipe 52 of a liquid cooling cabinet disposed near a side of the main pipe 42.

The main pipe is configured to transport cooling water.

According to the foregoing connection manner in which one end of the main pipe is fastened to the container body and the other end is not fastened, an impact of body deformation on the pipe can be avoided in a hoisting, transportation, and pile-up process of the container data center.

In addition, to further enhance a shock resistance capability of the liquid cooling cabinet in the container data center, as shown in FIG. 7, which shows a cross-sectional view of key parts near the main pipe, a bottom of the main pipe 4 is fastened to at least one wheel 6, all wheels at a bottom of each main pipe are limited to sliding in a chute 7 that is fastened at the bottom of the container body, and when the container body is deformed, all wheels at the bottom of each main pipe slide in the chute that is fastened at the bottom of the container body. For example, in the bottom view shown in FIG. 6, 5 wheels are disposed for each main pipe, where wheels of the main pipe 41 are marked as 6A, 6B, 6C, 6D, and 6E; and wheels of the main pipe 42 are marked as 6F, 6G, 6H, 6I, and 6J. In addition, if the main pipe needs to be maintained, the main pipe can be conveniently dragged out by using the wheels.

In addition, to reduce vibration between the wheels and the main pipe, preferably, as shown in FIG. 7, a rubber layer 8 is further wrapped around outside the main pipe.

In this way, shock absorption and shock resistance in a transportation process can be implemented.

A vibration and shock resistance measure may also be taken between the main pipe and the branch pipe. For example, a flexible rubber pipe is used as the branch pipe of the liquid cooling cabinet shown in FIG. 5. In this way, an impact on the branch pipe caused by asynchronous displacement of the liquid cooling cabinet and the main pipe upon vibration and a shock during transportation can be avoided, and the flexible rubber branch pipe can be mounted and maintained more easily.

In the foregoing embodiment, a top of at least one cabinet in each cabinet set is connected, in a movable manner, to a beam on a top of the container by using a screw, so as to implement position limiting. In a position limiting measure shown in FIG. 4, the foregoing position limiting measure is used at tops of two cabinets in one cabinet set. It should be noted that, when the number of cabinets in a cabinet set exceeds 3, if the foregoing position limiting measure is used on tops of two cabinets, preferably, two cabinets located at two ends of a direction in which the cabinets are arranged are selected. In this way, a position limiting effect is achieved for another cabinet that is disposed between the cabinets at the two ends.

The position limiting measure that implements a movable connection by using a screw and is shown in FIG. 4 is specifically as follows: A shaft sleeve 11 is disposed in a position that is on the beam on the top of the container and corresponding to the top of the at least one cabinet, a projection of the shaft sleeve is located on the top of the at least one cabinet, and the top of the at least one cabinet is connected, by using a screw, to the shaft sleeve 11 corresponding to the top of the at least one cabinet. Because the shaft sleeve has certain toughness, while position limiting is performed on the cabinet, certain swing space is reserved for the cabinet, so as to achieve an objective of shock absorption.

The foregoing merely discloses several specific embodiments of the present invention, but is not intended to limit the present invention. Any variations readily figured out by a person skilled in the art shall fall within the protection scope of the present invention.

What is claimed is:

1. A container data center, comprising:
a container body; and
at least one cabinet set that is arranged in the container body in one direction, wherein each cabinet set comprises at least one cabinet, a direction in which the at least one cabinet is arranged is perpendicular to the direction in which the cabinet set is arranged, bottoms of all cabinets in each cabinet set are fastened on one shock absorbing platform, and a bottom of the shock absorbing platform is fastened to a bottom of the container body by using multiple shock absorbers.

2. The container data center according to claim 1, wherein in each cabinet set, adjacent cabinets are disposed in a gapless manner.

3. The container data center according to claim 1, further comprising:
a cooling apparatus disposed inside the container body and configured to dissipate heat for the cabinet set.

4. The container data center according to claim 3, wherein the cooling apparatus comprises liquid cooling cabinets disposed at two ends of each cabinet set in a direction in which the at least one cabinet is arranged, each liquid cooling cabinet is connected, by using a branch pipe, to a main pipe extending in the direction in which the cabinet set is arranged, the main pipe is configured to transport cooling water, one end of the main pipe is fastened to the container body, and the other end is free and not fastened.

5. The container data center according to claim 4, wherein multiple main pipes are disposed, a bottom of each main pipe is fastened to at least one wheel, and when the container body is deformed, all wheels at the bottom of each main pipe slide in a chute that is fastened at the bottom of the container body.

6. The container data center according to claim 4, wherein the branch pipe is a rubber pipe.

7. The container data center according to claim 4, wherein a rubber layer is further wrapped around the main pipe.

8. The container data center according to claim 1, wherein a top of at least one cabinet in each cabinet set is connected, in a movable manner, to a beam on a top of the container by using a screw, so as to implement position limiting.

9. The container data center according to claim 8, wherein a shaft sleeve is disposed on the beam on the top of the container, a projection of the shaft sleeve is located on the top of the at least one cabinet, and the at least one cabinet is connected, by using a screw, to the shaft sleeve corresponding to the top of the at least one cabinet, so as to implement a movable connection to the beam on the top of the container.
